(19) United States
(12) Patent Application Publication
(10) Pub. No.: US 2026/0169242 A1
(43) Pub. Date: Jun. 18, 2026

(54) OPTICAL DEVICES AND METHODS OF MANUFACTURE

(71) Applicant: Taiwan Semiconductor Manufacturing Co., Ltd., Hsinchu (TW)

(72) Inventors: Chia-Ming Hung, Taipei City (TW); Chi-Yuan Shih, Hsinchu (TW); Wen-Chuan Tai, Hsinchu (TW); Fan Hu, Taipei City (TW); Chen-Hao Huang, Taoyuan City (TW)

(21) Appl. No.: 18/980,013

(22) Filed: Dec. 13, 2024

(51) Int. Cl. G02B 6/42; H01L 23/367

(52) U.S. Cl. CPC G02B 6/4273; G02B 6/4254; H10W 40/22

(57) ABSTRACT

Methods of manufacturing optical devices and the optical devices formed are presented wherein method include forming a dielectric material around a wafer, forming an opening within the dielectric material, sealing the opening by bonding a stack of semiconductor materials to the dielectric material; and forming at least one optical component using the stack of semiconductor materials.

### BACKGROUND

Electrical signaling and processing is one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a wafer and a first oxide, in accordance with some embodiments.

FIGS. 2A-2B illustrate formation of a thermal isolation structure, in accordance with some embodiments.

FIG. 3 illustrates formation of a stack of semiconductor materials, in accordance with some embodiments.

FIG. 4 illustrates a bonding, in accordance with some embodiments.

FIG. 5 illustrates a thinning of a second substrate, in accordance with some embodiments.

FIG. 6 illustrates a removal of the second substrate, in accordance with some embodiments.

FIG. 7 illustrates a recessing process, in accordance with some embodiments.

FIG. 8 illustrates a removal of an etch stop layer, in accordance with some embodiments.

FIG. 9 illustrates a removal of another etch stop layer, in accordance with some embodiments.

FIG. 10 illustrates a regrowth of semiconductor material, in accordance with some embodiments.

FIG. 11 illustrates a thinning of the regrown material, in accordance with some embodiments.

FIG. 12 illustrates formation of an optical engine, in accordance with some embodiments.

FIGS. 13A-13C illustrates additional arrangements of the thermal isolation structures, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described in which thermal isolation structures are formed within a silicon-on-insulator substrate used in the manufacture of an optical engine. The thermal isolation structures are utilized to help block heat from transiting away from heaters used to stabilize the optical devices. Such blocking helps to lower the operating temperature of the heaters and helps prevent thermal wear and tear on other devices. However, the embodiments presented herein are intended to be illustrative and are not intended to be limiting, as the ideas presented may be implemented in a wide variety of embodiments, and all such embodiments are fully intended to be included within the scope of the embodiments.

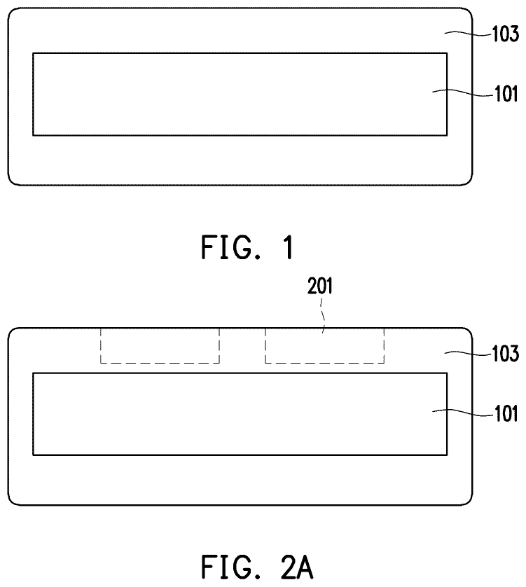

With respect now to FIG. 1, there is illustrated a wafer 101 and a first oxide 103 surrounding the wafer 101. In an embodiment, the wafer 101 may be a carrier wafer and comprises, e.g., a silicon substrate, although other substrates, such as a germanium substrate or other physical substrate, could be used. The wafer 101 may be a p-type semiconductor, although in other embodiments, it could be an n-type semiconductor.

The first oxide 103 may be formed surrounding the wafer 101. In an embodiment the first oxide 103 may be a dielectric material such as silicon oxide, although any suitable material may be used. The first oxide 103 may be formed using an oxide process, such as a rapid thermal oxide (RTO) process, although any other suitable thermal oxide treatment may be used. In the embodiments in which an RTO process is used, the wafer 101 may be placed into a rapid thermal chamber and heated to a temperature between about 100° C. and about 400° C., such as about 200° C., while the pressure of chamber is held to between about 10 torr and about 100 torr, such as about 20 torr and oxygen (O₂) may be flowed into the chamber at a flow rate of between about 1.0 slm and about 20.0 slm. During the thermal oxide treatment in embodiments in which the wafer 101 is silicon and in which oxygen is used as a reactant, the rapid thermal oxide process forms the first oxide 103 to be silicon oxide. However, any suitable material and process may be utilized.

By using the rapid thermal oxide process, the first oxide 103 may be formed to surround the wafer 101 and cover each side of the wafer 101. In particular embodiments the first oxide 103 may be formed to have a thickness over a top surface and a bottom surface of between about 1.9 μm and 2 μm, such as about 1.95 μm. However, any suitable thickness may be utilized.

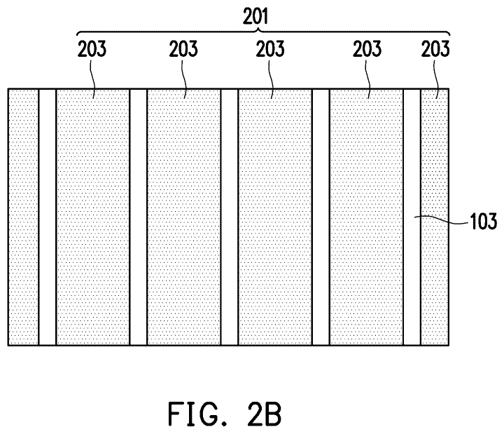

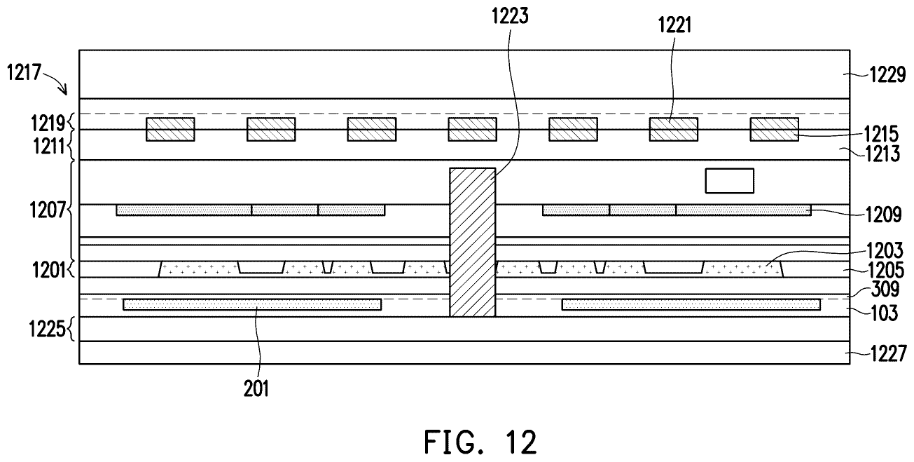

FIG. 2A illustrates that, once the first oxide 103 has been formed, the first oxide 103 may be patterned in order to form a thermal isolation structure (represented in FIG. 2A by the dashed boxes labeled 201). In an embodiment the thermal isolation structures 201 are utilized to increase the thermal resistance between subsequently formed optical devices 1203 and heaters 1209 (not illustrated in FIG. 2A but illustrated and discussed further below with respect to FIG. 12) and other devices, such as a printed circuit board 1227 (also not illustrated in FIG. 2A but illustrated and discussed further below with respect to FIG. 12). Such thermal isolation reduces the working temperature for devices such as heaters, thereby improving heater efficiency while also lowering concerns for impacts to underlying polyimide and underfill aging.

In a particular embodiment the thermal isolation structures 201 may be formed by patterning the first oxide 103 using, e.g., a photolithographic masking and etching process. For example, a photosensitive layer (not separately illustrated) such as a photoresist, a tri-layer photoresist, or the like, may be placed, imaged, and developed in order to form the desired pattern of the thermal isolation structures 201 within the photosensitive layer. Once the desired pattern is present, the pattern can be transferred to the underlying first oxide 103 using one or more etching processes, such as one or more reactive ion etching processes. However, any suitable processes or combination of processes may be utilized in order to form the thermal isolation structures 201 within the first oxide 103.

FIG. 2B illustrates a top down view of the thermal isolation structures 201 after they have been formed into the top surface of the thermal isolation structure 201. In the embodiment illustrated in FIG. 2B, the thermal isolation structures 201 may be formed as a series of individual, parallel lines 203. However, any suitable pattern may be utilized.

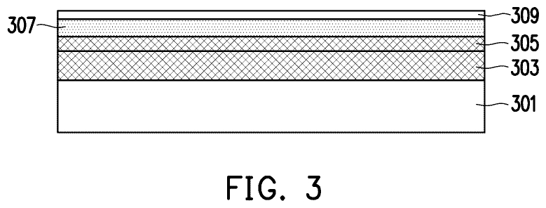

FIG. 3 illustrates a plurality of layers formed on a second substrate 301 that will be bonded to the first oxide 103. In an embodiment the plurality of layers comprises a first etch stop layer 303, a second etch stop layer 305, an epitaxial semiconductor layer 307, and a bonding layer 309. Looking first at the second substrate 301, the second substrate 301 may be a device wafer and comprises, e.g., a silicon substrate, although other substrates, such as a germanium substrate or other physical substrate, could be used. The second substrate 301 may be a p-type semiconductor material, such as a P⁺ semiconductor material, although in other embodiments, it could be an n-type semiconductor.

The first etch stop layer 303 is formed on the second substrate 301 and may be another semiconductor material that provides etch selectivity to the underlying second substrate 301. In a particular embodiment in which the second substrate 301 is a P⁺ semiconductor material such as silicon, the first etch stop layer 303 comprises a semiconductor material such as silicon with a lower concentration of p-type dopants, such as P-silicon. The first etch stop layer 303 may be formed using an epitaxial growth process, although any suitable method of formation may be utilized.

The second etch stop layer 305 is formed over the first etch stop layer 303 and may be yet another semiconductor material that provides etch selectivity to the underlying first etch stop layer 303. In a particular embodiment in which the first etch stop layer 305 is a P-semiconductor material such as silicon, the second etch stop layer 305 may be a semiconductor material such as silicon germanium. The second etch stop layer 305 may be formed using an epitaxial growth process, although any suitable method of formation may be utilized.

The first semiconductor layer 307 may be formed over the second etch stop layer 305 and will eventually be used as a seed layer to grow a top semiconductor material 1001 (described further below with respect to FIG. 10). In a particular embodiment the first semiconductor layer 307 may be a semiconductor material such as silicon or silicon germanium formed using a process such as epitaxial growth. As such, by using growth processes such as epitaxial growth processes, the first semiconductor layer 307 may have a similar crystalline structure as the second substrate 301 (with some changes based on the crystalline structures of the intervening layers). However, any suitable materials and methods may be utilized.

The bonding layer 309 is formed on the first semiconductor layer 307 and will be utilized to bond the first semiconductor layer 307 to the first oxide 103. In an embodiment the bonding layer 309 may be a material such as silicon oxide formed using a plasma process such as a high density plasma oxide process. The bonding layer 309 may be formed to a thickness of between about 0.02 μm and about 0.8 μm, such as about 0.05 μm. However, any suitable material and method of manufacture may be utilized.

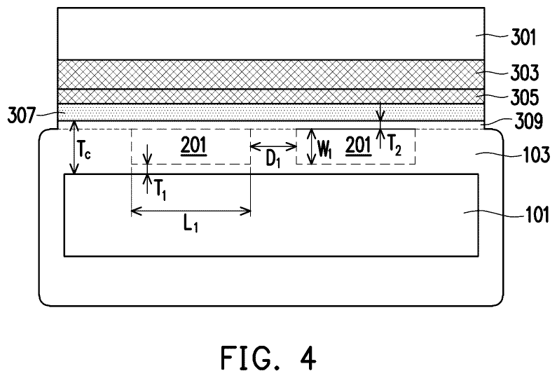

FIG. 4 illustrates a bonding of the bonding layer 309 to the first oxide 103 and a sealing of the thermal isolation structures 201 to form buried cavities. In an embodiment the bonding layer 309 and the first oxide 103 may be bonded using a dielectric-to-dielectric, fusion bonding process. In a particular embodiment which utilizes a dielectric-to-dielectric bonding process, the process may be initiated by activating the surfaces of the bonding layer 309 and the first oxide 103, including the sidewalls and bottom surface of the thermal isolation structures 201 (while they are exposed). Activating the top surfaces of the bonding layer 309 and the first oxide 103 may comprise a dry treatment, a wet treatment, a plasma treatment, exposure to an inert gas plasma, exposure to H₂O, H₂, exposure to N₂, exposure to O₂, combinations thereof, or the like, as examples. In embodiments where a wet treatment is used, an RCA cleaning may be used, for example. In another embodiment, the activation process may comprise other types of treatments.

In an embodiment in which both the first oxide 103 and the bonding layer 309 comprise silicon oxide, the activation process forms dangling OH⁻ bonds along the surface according to, in some embodiments, the following equation:

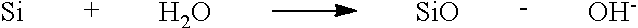

As such, each exposed surface, including the exposed surfaces of the thermal isolation structures 201, are at least partially modified to have OH⁻ dangling bonds. This modification assists in the subsequent steps of bonding between the bonding layer 309 and the first oxide 103.

Additionally, during some embodiments of the activation process, the process is performed at a pressure less than atmospheric pressure, such as running at vacuum. As such, after the activation process, the thermal isolation structures 201 may have the OH⁻ dangling bonds and also have a vacuum instead of being filled by ambient atmosphere. In other embodiments the thermal isolation structures 201 may be filled with ambient atmosphere, which still provides thermal benefits.

After the activation process the bonding layer 309 and the first oxide 103 may be cleaned using, e.g., a chemical rinse, which may provide additional dangling bonds if they have not been previously formed, and then the bonding layer 309 is aligned and placed into physical contact with the first oxide 103. At this point in the process, the dangling OH⁻ bonds will hydrogen bond with each other to provide an initial bonding between the bonding layer 309 and the first oxide 103. However, the hydrogen bonding in generally weak at this point.

Once in physical contact, the bonding layer 309 and the first oxide 103 are then subjected to thermal treatment and contact pressure to convert the hydrogen bonds into covalent bonds. In an embodiment, the bonding layer 309 and the first oxide 103 may be subjected to a pressure of about 200 kPa or less, and a temperature between about 25° C. and about 250° C. in an environment such as nitrogen (N₂) to fuse the bonding layer 309 and the first oxide 103. However, any suitable process conditions can be utilized.

During the annealing process, the OH⁻ dangling bonds will disassociate and dehydrate according to, in some embodiments, the following equation:

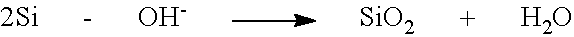

In this manner, with the dissociation, the dangling bonds will convert to covalent bonds of silicon oxide between the bonding layer 309 and first oxide 103, and the bonding layer 309 and the first oxide 103 form a dielectric-to-dielectric, fusion bond. In some embodiments, the bonded devices are subsequently baked, annealed, pressed, or otherwise treated to strengthen or finalize the bond.

However, within the thermal isolation structures 201, the dangling bonds of OH⁻ do not have an adjacent dangling bond to covalently bond with. As such, the dangling bonds, when they disassociate, can, in some embodiments, react with the ambient gasses adjacent to the surfaces of the thermal isolation structure 201. As such, in embodiments in which the annealing process is performed with a nitrogen ambient, the sidewalls may react with the nitrogen to form, e.g., silicon oxynitride. In other embodiments the nitrogen may not react and simply diffuse into the sidewalls of the thermal isolation structure 201.

Additionally, during the annealing process, the thermal isolation structures 201 become sealed from the outside environment. As such, the ambient atmosphere during the annealing process, such as the nitrogen ambient at the reduced pressure, becomes sealed within the thermal isolation structures 201.

However, in other embodiments the annealing process may be performed at ambient temperature and pressure, and in an environment using atmospheric air. In such embodiments as this, the atmospheric air becomes sealed into the thermal isolation structure 201. Further, it is this environment that helps to provide the thermal insulation and blocking designed by the thermal isolation structures 201.

Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

After the annealing process the thermal isolation structures 201 are buried within the dielectric materials of the first oxide 103 and the bonding layer 309. In an embodiment the thermal isolation structures 201 may have a first width W₁ of between about 200 Å and about 23,000 Å and a first length L₁ of between about 0.2 μm and about 20 μm. Additionally, the individual thermal isolation structures 201 may be spaced apart from each other by a first distance D₁ of less than about 0.1 μm. However, any suitable distances may be utilized.

Additionally, given the processes described, the thermal isolation structures 201 may be buried within the various dielectric materials around the thermal isolation structures 201. For example, in an embodiment in which the first oxide 103 and the bonding layer 309 have a combined thickness T_{c} of between about 4,000 Å and about 25,000 Å, the first oxide 103 may have a first thickness T₁ of less than about 1,000 Å and the bonding layer 309 may have a second thickness T₂ of less than about 500 Å. However, any suitable thicknesses may be utilized.

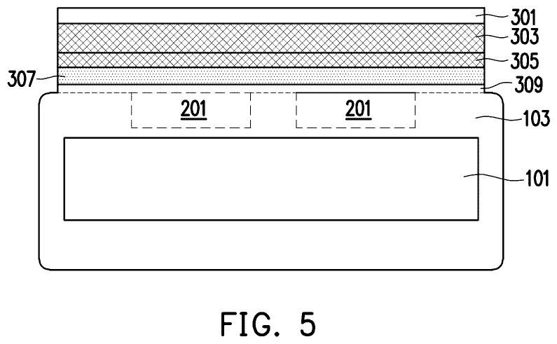

FIG. 5 illustrates a thinning process utilized in order to reduce the thickness of the second substrate 301. In an embodiment the thinning process may be a process such as a grinding process, and may be used to reduce the thickness of the second substrate 301. Additionally at this time edges of the second substrate 301 may be trimmed. However, any other suitable process, such as chemical mechanical polishing or even a series of one or more etches, may also be used. Any suitable method of thinning and trimming the second substrate 301 may be utilized.

Additionally, once the trimming process has been performed, a second thinning of the second substrate 301 may be performed. In an embodiment the second thinning of the second substrate 301 may be performed in a similar manner as the first thinning, such as by using a grinding process until the second substrate 301 has a thickness of about 25 μm. However, any suitable process and any suitable thickness may be utilized.

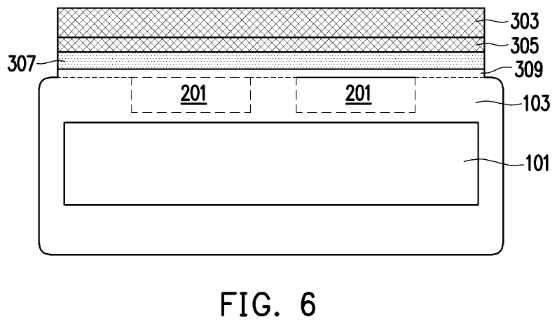

FIG. 6 illustrates that, once a majority of the second substrate 301 has been removed through the thinning processes, a remainder of the second substrate 301 may be removed to expose the first etch stop layer 303. In an embodiment the remainder of the second substrate 301 may be removed using one or more etching processes, such as a wet etching process using, e.g., Hydrofluoric Acid+Nitric Acid+Acetic Acid (HNA) as etchants. However, any suitable etching process and any suitable etchants may be utilized.

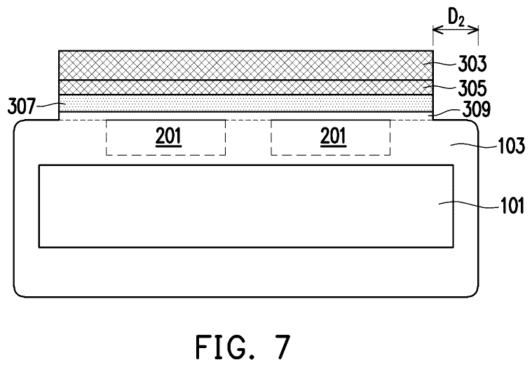

FIG. 7 illustrates that, once the second substrate 301 has been removed, a wafer edge etch (WEE) may be performed. In an embodiment the wafer edge etch may be one or more etches, such as a wet etch or a dry etch, that works to recess the edges of the first etch stop layer 303, the second etch stop layer 305, and the first semiconductor layer 307 from the edge of the first oxide 103 to be a second distance D2 of between about 0.5 mm and about 2 mm, such as about 1.2 mm. However, any suitable process and any suitable distance may be utilized.

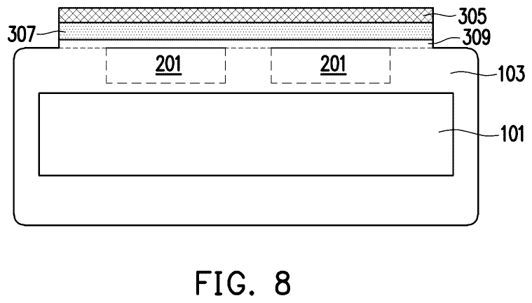

FIG. 8 illustrates a removal of the first etch stop layer 303 to expose the second etch stop layer 305. In an embodiment the first etch stop layer 303 may be removed using a combination of thinning processes and etching processes. For example, in one particular embodiment a thinning process such as a chemical mechanical polishing process may be utilized in order to thin down the first etch stop layer 303 to a thickness of about 5,000 Å. The thinning process may then be followed by an etching process, such as a wet etching process using TMAH as a reactant, in order to remove the remaining portions of the first etch stop layer 303. However, any suitable process or combination of processes may be utilized.

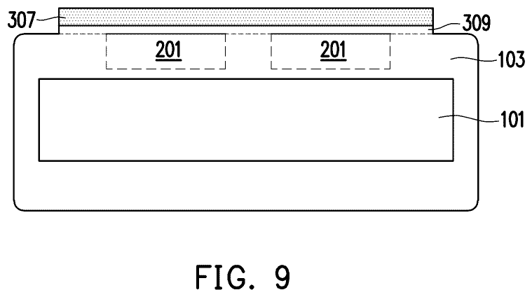

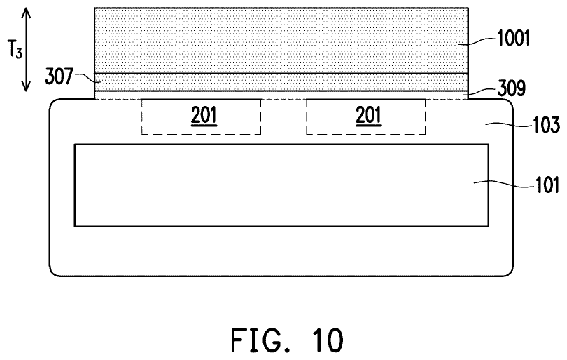

FIG. 9 illustrates a removal of the second etch stop layer 305 in order to expose the first semiconductor layer 307. In an embodiment the second etch stop layer 305 may be removed using one or more etching processes, such as a wet etching process. In other embodiments a thinning process such as a grinding process with 1 nm to 3 nm TTV control may be utilized. Any suitable method or combination of methods may be utilized in order to remove the second etch stop layer 305 and expose the first semiconductor layer 307.

FIG. 10 illustrates that, once the second etch stop layer 305 has been removed, and the first semiconductor layer 307 has a thickness of about 100 nm, a top semiconductor material 1001 may be regrown on the first semiconductor layer 307. In an embodiment in which the first semiconductor layer 307 is a semiconductor material such as silicon, the top semiconductor material 1001 may be regrown on top of the first semiconductor layer 307 using a growth process such as epitaxial growth, until the first semiconductor layer 307 and the top semiconductor material 1001 collectively have a third thickness T₃ of between about 120 nm and about 310 nm, such as about 400 nm. However, any suitable thickness may be utilized.

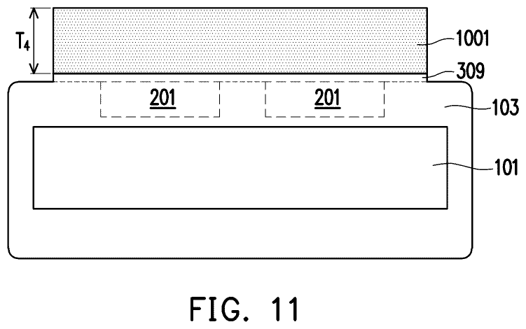

FIG. 11 illustrates that, after the growth of the top semiconductor material 1001, the top semiconductor material 1001 may be thinned to its final thickness (with the first semiconductor layer 307 removed in FIG. 11 for clarity). In an embodiment the thinning may be performed using a polishing process such as a chemical mechanical polishing process or a grinding process, although any suitable process may be utilized. The top semiconductor material may be thinned to a final, fourth thickness T₄ of semiconductor material over the first oxide 103 of between about 600 Å and about 5,000 Å, such as about 3050 Å. However, any suitable thickness may be utilized.

FIG. 12 illustrates that, once the top semiconductor material 1001 is ready, first optical components 1203 for a first active layer 1201 are manufactured using the top semiconductor material 1001 for the first active layer 1201. In embodiments the first optical components 1203 of the first active layer 1201 may include such components as optical waveguides (e.g., ridge waveguides, rib waveguides, buried channel waveguides, diffused waveguides, etc.), couplers (e.g., grating couplers, edge couplers that are a narrowed waveguide with a width of between about 1 nm and about 200 nm, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable first optical components 1203 may be used.

To begin forming the first active layer 1201 of first optical components 1203 from the initial material, the top semiconductor material 1001 for the first active layer 1201 may be patterned into the desired shapes for the first active layer 1201 of first optical components 1203. In an embodiment the top semiconductor material 1001 for the first active layer 1201 may be patterned using, e.g., one or more photolithographic masking and etching processes. However, any suitable method of patterning the top semiconductor material 1001 for the first active layer 1201 may be utilized. For some of the first optical components 1203, such as waveguides or edge couplers, the patterning process may be all or at least most of the manufacturing that is used to form these first optical components 1203 components.

For those components that utilize further manufacturing processes, such as Mach-Zehnder silicon-photonic switches that utilize resistive heating elements, additional processing may be performed either before or after the patterning of the material for the first active layer 1201. For example, implantation processes, additional deposition and patterning processes for different materials (e.g., resistive heating elements, III-V materials for converters), combinations of all of these processes, or the like, can be utilized to help further the manufacturing of the various desired first optical components 1203. In a particular embodiment, in some embodiments an epitaxial deposition of a semiconductor material such as germanium (used, e.g., for electricity/optics signal modulation and transversion) may be performed on a patterned portion of the top semiconductor material 1001 of the first active layer 1201. In such an embodiment the semiconductor material may be epitaxially grown in order to help manufacture, e.g., a photodiode for an optical-to-electrical converter. All such manufacturing processes and all suitable first optical components 1203 may be manufactured, and all such combinations are fully intended to be included within the scope of the embodiments.

Once the individual first optical components 1203 of the first active layer 1201 have been formed, a second insulator layer 1205 may be deposited to cover the first optical components 1203 and provide additional cladding material. In an embodiment the second insulator layer 1205 may be a dielectric layer that separates the individual components of the first active layer 1201 from each other and from the overlying structures and can additionally serve as another portion of cladding material that surrounds the first optical components 1203. In an embodiment the second insulator layer 1205 may be silicon oxide, silicon nitride, germanium oxide, germanium nitride, combinations of these, or the like, formed using a deposition method such as chemical vapor deposition, atomic layer deposition, physical vapor deposition, combinations of these, or the like. Once the material of the second insulator layer 1205 has been deposited, the material may be planarized using, e.g., a chemical mechanical polishing process in order to either planarize a top surface of the second insulator layer 1205 (in embodiments in which the second insulator layer 1205 is intended to fully cover the first optical components 1203) or else planarize the second insulator layer 1205 with top surfaces of the first optical components 1203. However, any suitable material and method of manufacture may be used.

Once the first optical components 1203 of the first active layer 1201 have been manufactured and the second insulator layer 1205 has been formed, first metallization layers 1207 are formed in order to electrically connect the first active layer 1201 of first optical components 1203 to control circuitry, to each other, and to subsequently attached devices. In an embodiment the first metallization layers 1207 are formed of alternating layers of dielectric and conductive material and may be formed through any suitable processes (such as deposition, damascene, dual damascene, etc.) to a thickness of about 5.81 μm. In particular embodiments there may be multiple layers of metallization used to interconnect the various first optical components 1203, but the precise number of first metallization layers 1207 is dependent upon the design of the device.

Additionally, during the manufacture of the first metallization layers 1207, one or more second optical components (not separately illustrated in FIG. 12) may be formed as part of the first metallization layers 1207. In some embodiments the second optical components of the first metallization layers 1207 may include such components as couplers (e.g., edge couplers, grating couplers, etc.) for connection to outside signals, optical waveguides (e.g., ridge waveguides, rib waveguides, buried channel waveguides, diffused waveguides, etc.), optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable optical components may be used for the one or more second optical components.

In an embodiment the one or more second optical components may be formed by initially depositing a material for the one or more second optical components. In an embodiment the material for the one or more second optical components may be a dielectric material such as silicon nitride, silicon oxide, combinations of these, or the like, or a semiconductor material such as silicon, deposited using a deposition method such as chemical vapor deposition, atomic layer deposition, physical vapor deposition, combinations of these, or the like. However, any suitable material and any suitable method of deposition may be utilized.

Once the material for the one or more second optical components has been deposited or otherwise formed, the material may be patterned into the desired shapes for the one or more second optical components. In an embodiment the material of the one or more second optical components may be patterned using, e.g., one or more photolithographic masking and etching processes. However, any suitable method of patterning the material for the one or more second optical components may be utilized.

For some of the one or more second optical components, such as waveguides or edge couplers, the patterning process may be all or at least most manufacturing that is used to form these components. Additionally, for those components that utilize further manufacturing processes, such as Mach-Zehnder silicon-photonic switches that utilize resistive heating elements, additional processing may be performed either before or after the patterning of the material for the one or more second optical components. For example, implantation processes, additional deposition and patterning processes for different materials, combinations of all of these processes, or the like, and can be utilized to help further the manufacturing of the various desired one or more second optical components. All such manufacturing processes and all suitable one or more second optical components may be manufactured, and all such combinations are fully intended to be included within the scope of the embodiments.

Additionally, during the manufacturing of the first metallization layers 1207, heaters 1209 may be manufactured in order to provide a controlled environment for the underlying optical devices. In an embodiment the heaters 1209 may be, for example, resistive heaters formed by first depositing and patterning a conductive material with a desired resistivity, and then connecting the conductive material with conductive lines and vias of the first metallization layer 1207. In operation, the current put through the conductive material with the desired resistivity will generate heat that then spreads to the first optical components 1203. However, any suitable type of heater, and any suitable method of manufacture, may be utilized.

Once the heaters 1209 and other components of the first metallization layers 1207 have been manufactured, a first bonding layer 1211 is formed over the first metallization layers 1207. In an embodiment, the first bonding layer 1211 may be used for a dielectric-to-dielectric and metal-to-metal bond. In accordance with some embodiments, the first bonding layer 1211 is formed of a first dielectric material 1213 such as silicon oxide, silicon nitride, polyimide, or the like. The first dielectric material 1213 may be deposited using any suitable method, such as CVD, high-density plasma chemical vapor deposition (HDPCVD), PVD, atomic layer deposition (ALD), or the like. However, any suitable materials and deposition processes may be utilized.

Once the first dielectric material 1213 has been formed, first openings in the first dielectric material 1213 are formed to expose conductive portions of the underlying layers in preparation to form first pads 1215 within the first bonding layer 1211. Once the first openings have been formed within the first dielectric material 1213, the first openings may be filled with a seed layer and a plate metal to form the first pads 1215 within the first dielectric material 1213. The seed layer may be blanket deposited over top surfaces of the first dielectric material 1213 and the exposed conductive portions of the underlying layers and sidewalls of the first openings. The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like. The plate metal may be a fill material. A barrier layer (not separately illustrated) may be blanket deposited over top surfaces of the first dielectric material 1213 and sidewalls of the openings and the second openings before the seed layer. The barrier layer may comprise titanium, titanium nitride, tantalum, tantalum nitride, or the like.

Following the filling of the first openings, a planarization process, such as a CMP, is performed to remove excess portions of the seed layer and the plate metal, forming the first pads 1215 within the first bonding layer 1211. In some embodiments a bond pad via (not separately illustrated) may also be utilized to connect the first pads 1215 with underlying conductive portions and, through the underlying conductive portions, connect the first pads 1215 with the first metallization layers 1207.

Additionally, the first bonding layer 1211 may also include one or more third optical components (not separately illustrated) incorporated within the first bonding layer 1211. In such an embodiment, prior to the deposition of the first dielectric material 1213, the one or more third optical components may be manufactured using similar methods and similar materials as the one or more second optical components (described above), such as by being waveguides and other structures formed at least in part through a deposition and patterning process. However, any suitable structures, materials and any suitable methods of manufacture may be utilized.

FIG. 12 additionally illustrates a bonding of a first semiconductor device 1217 to the first bonding layer 1211. In some embodiments, the first semiconductor device 1217 is an electronic integrated circuit (EIC—e.g., a device without optical devices) and may have a semiconductor substrate, a layer of active devices, an overlying interconnect structure, a second bonding layer 1219, and associated second bond pads 1221. In an embodiment the semiconductor substrate may be similar to the wafer 101 (e.g., a semiconductor material such as silicon or silicon germanium), the active devices may be transistors, capacitors, resistors, and the like formed over the semiconductor substrate, the interconnect structure may be similar to the first metallization layers 1207 (without optical components) and formed to a thickness of about 4 μm, the second bonding layer 1219 may be similar to the first bonding layer 1211, and the second bond pads 1221 may be similar to the first pads 1215. However, any suitable devices may be utilized.

In an embodiment the first semiconductor device 1217 may be configured to work with the first optical components 1203 for a desired functionality. In some embodiments the first semiconductor device 1217 may be a high bandwidth memory (HBM) module, an xPU, a logic die, a 3DIC die, a CPU, a GPU, a SoC die, a MEMS die, combinations of these, or the like. Any suitable device with any suitable functionality, may be used, and all such devices are fully intended to be included within the scope of the embodiments.

In an embodiment the first semiconductor device 1217 and the first bonding layer 1211 may be bonded using a dielectric-to-dielectric and metal-to-metal bonding process. In a particular embodiment which utilizes a dielectric-to-dielectric and metal-to-metal bonding process, the process may be initiated by activating the surfaces of the second bonding layer 1219 and the surfaces of the first bonding layer 1211. Activating the top surfaces of the first bonding layer 1211 and the second bonding layer 1219 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the bonding of the first bonding layer 1211 and the second bonding layer 1219.

After the activation process the first bonding layer 1211 and the second bonding layer 1219 may be cleaned using, e.g., a chemical rinse, and then the first semiconductor device 1217 is aligned and placed into physical contact with the first bonding layer 1211. The devices are then subjected to thermal treatment and contact pressure to bond the devices together. For example, the first bonding layer 1211 and the second bonding layer 1219 may be subjected to a pressure of about 200 kPa or less, and a temperature between about 25° C. and about 250° C. to fuse the first bonding layer 1211 and the second bonding layer 1219. The first bonding layer 1211 and the second bonding layer 1219 may then be subjected to a temperature at or above the eutectic point for material of the first pads 1215 and the second bond pads 1221, e.g., between about 150° C. and about 650° C., to fuse the metal. In this manner, the first bonding layer 1211 and the second bonding layer 1219 form a dielectric-to-dielectric and metal-to-metal bonded device. In some embodiments, the bonded dies are subsequently baked, annealed, pressed, or otherwise treated to strengthen or finalize the bond.

Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

FIG. 12 additionally illustrates a formation and attachment of a support substrate 1229 to the first semiconductor device 1217. In an embodiment the support substrate 1229 may be a support material that is transparent to the wavelength of light that is desired to be used, such as silicon, with a thickness of about 787 μm. However, any suitable material may be utilized. The support substrate 1229 may further comprise one or more first coupling lens (not separately illustrated in FIG. 12) positioned to facilitate movement from an external source of optical signals such as a fiber array unit (not illustrated in FIG. 12). In an embodiment the first coupling lens may be formed by shaping the material of the support substrate (e.g., silicon) using masking and etching processes. However, any suitable process may be utilized.

FIG. 12 additionally illustrates a removal of the wafer 101, thereby exposing the first oxide 103 surrounding the thermal isolation structure 201. In an embodiment the wafer 101 may be removed using a planarization process, such as a chemical mechanical polishing process, a grinding process, one or more etching processes, combinations of these, or the like. However, any suitable method may be used in order to remove the wafer 101.

Once the first substrate 101 has been removed, an optional second active layer of fourth optical components (not separately illustrated in FIG. 12) may be formed on a back side of the first oxide 103 around the thermal isolation structure 201. In an embodiment the second active layer of fourth optical components may be formed using similar materials and similar processes as the second optical components of the first metallization layers 1207 (described above). For example, the second active layer of fourth optical components may be formed of alternating layers of a cladding material such as silicon oxide and core material such as silicon nitride formed using deposition and patterning processes in order to form optical components such as waveguides and the like.

FIG. 12 additionally illustrates formation of first through device vias (TDVs) 1223 and formation of a third bonding layer 1225. In an embodiment the first through device vias 1223 extend through the second active layer and the first active layer 1201 so as to provide a quick passage of power, data, and ground through the desired layers. In an embodiment the first through device vias 1223 may be formed by initially forming through device via openings through the desired layers. The through device via openings may be formed by applying and developing a suitable photoresist (not shown), and removing portions of the layers that are exposed.

Once the through device via openings have been formed, the through device via openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may also be used.

Once the liner has been formed along the sidewalls and bottom of the through device via openings, a barrier layer (also not independently illustrated) may be formed and the remainder of the through device via openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer (not shown), filling and overfilling the through device via openings. Once the through device via openings have been filled, excess liner, barrier layer, seed layer, and first conductive material outside of the through device via openings may be removed through a planarization process such as chemical mechanical polishing (CMP), although any suitable removal process may be used.

Optionally, in some embodiments once the first through device vias 1223 have been formed, second metallization layers (not separately illustrated in FIG. 12) may be formed in electrical connection with the first through device vias 1223. In an embodiment the second metallization layers may be formed as described above with respect to the first metallization layers 1207, such as being alternating layers of dielectric and conductive materials using damascene processes, dual damascene process, or the like. In other embodiments, the second metallization layers may be formed using a plating process to form and shape conductive material, and then cover the conductive material with a dielectric material. However, any suitable structures and methods of manufacture may be utilized.

The third bonding layer 1225 is formed in order to provide electrical connections to subsequently attached devices. In an embodiment the third bonding layer 1225 may be similar to the first bonding layer 1211, such as having a dielectric material such as polyimide (to a thickness of about 13 μm), silicon oxide, or the like, third bond pads (not separately illustrated but similar to the first pads 1215) and even fifth optical components (also not separately illustrated but similar to the third optical components 511). However, any suitable devices may be utilized.

Once the third bonding layer 1225 has been formed, first external connectors may be placed on the third bonding layer 1225 to bond the device to an external substrate 1227. The first external connectors may be conductive bumps (e.g., C4 bumps, ball grid arrays, microbumps, etc.) or conductive pillars utilizing materials such as solder and copper. In an embodiment in which the first external connectors are contact bumps, the first external connectors may comprise a material such as tin, or other suitable materials, such as silver, lead-free tin, or copper. In an embodiment in which the first external connectors are tin solder bumps, the first external connectors may be formed by initially forming a layer of tin through such commonly used methods such as evaporation, electroplating, printing, solder transfer, ball placement, etc. Once a layer of tin has been formed on the structure, a reflow may be performed in order to shape the material into the desired bump shape.

The external substrate 1227 may be a package substrate, which may be a printed circuit board (PCB) or the like. The external substrate 1227 may include one or more dielectric layers and electrically conductive features, such as conductive lines and vias and may have a thickness of about 1 mm. In some embodiments, the external substrate 1227 may include through-vias, active devices, passive devices, and the like. The external substrate 1227 may further include conductive pads formed at the upper and lower surfaces of the external substrate 1227.

Once the first external connectors have been formed, the first external connectors may be attached to the external substrate 1227. In an embodiment the external substrate 1227 and the first external connectors may be attached by initially aligning the first external connectors with the external substrate 1227. Once aligned and in physical contact, the first external connectors are reflowed by raising the temperature of the first external connectors past a eutectic point of the first external connectors, thereby shifting the material of the first external connectors to a liquid phase. Once reflowed, the temperature is reduced in order to shift the material of the first external connectors back to a solid phase.

Optionally, a first underfill material (not separately illustrated) may be placed around the first external connectors. The first underfill material may reduce stress and protect the joints resulting from the reflowing of the first external connectors. The first underfill material may be formed by a capillary flow process after the attaching has been performed and may have a thickness of about 60 μm.

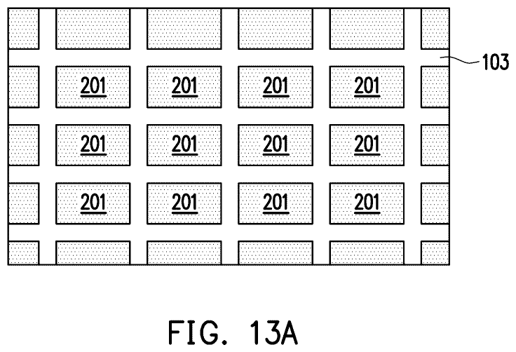

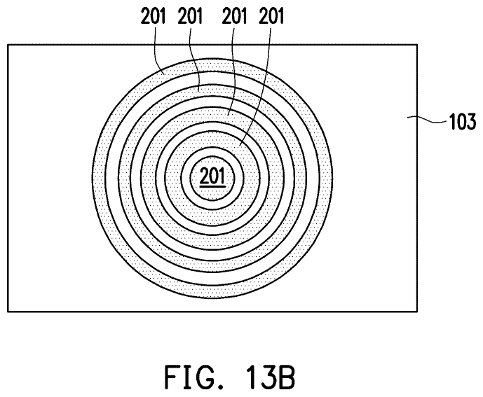

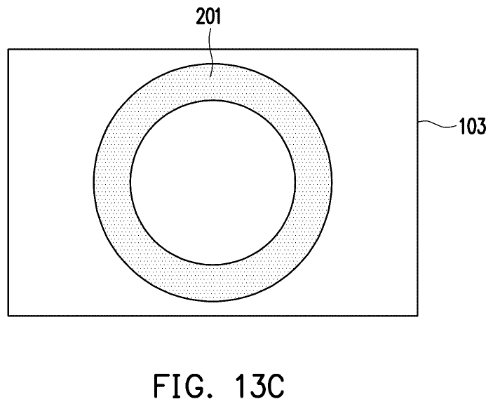

FIGS. 13A-13C illustrate top down views of additional embodiments of the thermal isolation structures 201 arranged in different variations. Looking first at the embodiment illustrated in FIG. 13A, the thermal isolation structures 201 are arranged as rectangular structures surrounded by the first oxide 103. Additionally, while the thermal isolation structures 201 in this embodiment are arranged evenly, in other embodiments the thermal isolation structures 201 may be in a staggered arrangement.

Looking next at the embodiment illustrated in FIG. 13B, in this embodiment the thermal isolation structures 201 are arranged as a plurality of circles. Additionally, the individual ones of the plurality of circles are embedded within each other to form a bullseye pattern. Additionally, while the thermal isolation structures 201 in this embodiment are arranged evenly, in other embodiments the thermal isolation structures 201 may be arranged with different spacing between the individual circles.

Finally, looking at the embodiment illustrated in FIG. 13C, in this embodiment the thermal isolation structures 201 are again formed as a circle. In this embodiment, however, instead of having a plurality of circles embedded within each other (as in FIG. 13B above), the thermal isolation structures 201 in this embodiment are formed as a single circle within the first oxide 103. As such, a larger amount of thermal isolation may be obtained. Any suitable shape, arrangement, or combinations of shapes and arrangement may be utilized, and all such arrangements are fully intended to be included within the scope of the embodiments.

By utilizing the thermal isolation structure 201 within the first oxide 103, the thermal isolation structure 201 can help to increase the efficiency of the heaters 1209. In particular, by lowering the amount of heat dissipated to the surrounding environment, the operating temperature of the heaters 1209 may be reduced, thereby helping to prolong the lifetime of the heaters 1209. Additionally, by reducing the amount of heat that reaches the third bonding layer 1225 or the first underfill material, these materials will experience less thermal related fatigue and help to improve the reliability of these materials.

In accordance with an embodiment, a method of manufacturing an optical device includes: forming a dielectric material around a wafer; forming an opening within the dielectric material; sealing the opening by bonding a stack of semiconductor materials to the dielectric material; and forming at least one optical component using the stack of semiconductor materials. In an embodiment the sealing is performed with a fusion bonding process. In an embodiment after the sealing nitrogen fills the opening. In an embodiment after the sealing air fills the opening. In an embodiment after the sealing a vacuum is present within the opening. In an embodiment the method further includes removing the wafer. In an embodiment the method further includes forming a heater over the at least one optical component.

In accordance with another embodiment, a method of manufacturing an optical device includes: forming a buried cavity within a silicon on insulator substrate; forming optical components and at least one heater over a first side of the buried cavity; and forming a dielectric material on a second side of the buried cavity, wherein the buried cavity thermally isolates the at least one heater from the dielectric material. In an embodiment the forming the buried cavity further includes: forming an opening within the silicon on insulator substrate; and sealing the opening with a second dielectric material. In an embodiment the sealing is performed by bonding the dielectric material to the silicon on insulator substrate. In an embodiment the bonding is performed at least in part with a fusion bonding process. In an embodiment the bonding bonds a stack of semiconductor materials to the silicon on insulator substrate. In an embodiment the opening is one of a plurality of openings, the plurality of openings being arranged in parallel lines. In an embodiment the method further includes: placing external connectors on the second side of the buried cavity; bonding the external connectors to a printed circuit board; and placing an underfill material around the external connectors.

In accordance with yet another embodiment, an optical device includes: a first buried cavity within a first dielectric material; first optical components and a heater on a first side of the first buried cavity; and a second dielectric material on a second side of the first buried cavity opposite the first side, wherein the first buried cavity thermally isolates the second dielectric material from the heater. In an embodiment the first buried cavity is part of a plurality of buried cavities, the plurality of buried cavities being arranged in parallel lines. In an embodiment the first buried cavity is part of a plurality of buried cavities, each of the plurality of buried cavities being rectangular in shape. In an embodiment the first buried cavity is part of a plurality of buried cavities, the plurality of buried cavities being circular in shape. In an embodiment the plurality of buried cavities are embedded within each other. In an embodiment the first buried cavity is filled with nitrogen.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an optical device, the method comprising:
forming a dielectric material around a wafer;
forming an opening within the dielectric material;
sealing the opening by bonding a stack of semiconductor materials to the dielectric material; and
forming at least one optical component using the stack of semiconductor materials.

2. The method of claim 1, wherein the sealing is performed with a fusion bonding process.

3. The method of claim 2, wherein after the sealing nitrogen fills the opening.

4. The method of claim 2, wherein after the sealing air fills the opening.

5. The method of claim 1, wherein after the sealing a vacuum is present within the opening.

6. The method of claim 1, further comprising removing the wafer.

7. The method of claim 1, further comprising forming a heater over the at least one optical component.

8. A method of manufacturing an optical device, the method comprising:
forming a buried cavity within a silicon on insulator substrate;
forming optical components and at least one heater over a first side of the buried cavity; and
forming a dielectric material on a second side of the buried cavity, wherein the buried cavity thermally isolates the at least one heater from the dielectric material.

9. The method of claim 8, wherein the forming the buried cavity further comprises:
forming an opening within the silicon on insulator substrate; and
sealing the opening with a second dielectric material.

10. The method of claim 9, wherein the sealing is performed by bonding the dielectric material to the silicon on insulator substrate.

11. The method of claim 10, wherein the bonding is performed at least in part with a fusion bonding process.

12. The method of claim 10, wherein the bonding bonds a stack of semiconductor materials to the silicon on insulator substrate.

13. The method of claim 9, wherein the opening is one of a plurality of openings, the plurality of openings being arranged in parallel lines.

14. The method of claim 8, further comprising:
placing external connectors on the second side of the buried cavity;
bonding the external connectors to a printed circuit board; and
placing an underfill material around the external connectors.

15. An optical device comprising:
a first buried cavity within a first dielectric material;
first optical components and a heater on a first side of the first buried cavity; and
a second dielectric material on a second side of the first buried cavity opposite the first side, wherein the first buried cavity thermally isolates the second dielectric material from the heater.

16. The optical device of claim 15, wherein the first buried cavity is part of a plurality of buried cavities, the plurality of buried cavities being arranged in parallel lines.

17. The optical device of claim 15, wherein the first buried cavity is part of a plurality of buried cavities, each of the plurality of buried cavities being rectangular in shape.

18. The optical device of claim 15, wherein the first buried cavity is part of a plurality of buried cavities, the plurality of buried cavities being circular in shape.

19. The optical device of claim 18, wherein the plurality of buried cavities are embedded within each other.

20. The optical device of claim 15, wherein the first buried cavity is filled with nitrogen.
